(19) United States
(12) Patent Application Publication
(10) Pub. No.: US 2011/0074451 A1
(43) Pub. Date: Mar. 31, 2011

(54) PARTICLE MEASURING APPARATUS

(75) Inventor: Katsuaki YAMAGUCHI, Kobe-shi (JP)

(73) Assignee: SYSMEX CORPORATION, Kobe-shi (JP)

(21) Appl. No.: 12/887,941

(22) Filed: Sep. 22, 2010

(30) Foreign Application Priority Data
Sep. 25, 2009 (JP) 2009-220880

(51) Int. Cl. G01R 27/08

(52) U.S. Cl. 324/693

(57) ABSTRACT

A particle measuring apparatus comprising: a detection device with an aperture through which pass particles contained in a particle suspension liquid, for detecting a signal generated when a particle passes through the aperture; and a detection device supporting part comprising an elastic body, for supporting the detection device through the elastic body is disclosed.

### RELATED APPLICATIONS

This application claims priority under 35 U.S.C. §119 to Japanese Patent Application No. 2009-220880 filed on Sep. 25, 2009, the entire content of which is hereby incorporated by reference.

### FIELD OF THE INVENTION

The present invention relates to a particle measuring apparatus for measuring the size of a particle from a signal obtained when a particle within a particle suspension liquid passes through a aperture provided in a detection device.

### BACKGROUND

There are various conventional particle diameter measuring apparatuses for detecting particles such as fine ceramic particles, pigments, cosmetic powders and the like contained in particle suspension liquids (for example, refer to Japanese Registered Utility Model No. 6-22203). Japanese Registered Utility Model No. 6-22203 discloses a particle diameter measuring apparatus including a detection device configured by a tubular detection body with a mounted pellet having a pore, external electrode disposed outside the detection body, and an internal electrode disposed inside the detection body.

The particle detection device is immersed in a liquid preparation accommodated within a container. When the liquid preparation is aspirated through the particle detection device via a syringe provided in the apparatus, the particles in the liquid preparation pass through the aperture of the pellet and move into the particle detection device. The electrical resistance changes at the aperture when an electrical current flows from the internal electrode toward the external electrode and a particle passes through the pore, thus generating a pulse signal corresponding to the size of the particle passing between the two electrodes. The particle is detected and the size of the particle measured based on the pulse signal.

In the apparatus disclosed in Japanese Registered Utility Model No. 6-22203, it becomes difficult to distinguish the noise from the signal obtained from the particle when the size of the detection target particle diverges from the diameter of the pore. Generally, when the size of the particle is smaller than approximately 2% of the pore, it becomes difficult to distinguish the noise from the signal from the particle.

Therefore, the size of the aperture must variable according to the size of the detection target particle. Since it is essential to distinguish noise from a weak signal generated from a very fine particle particularly when specifically detecting such fine particles, the diameter of the aperture must become smaller to conform to the fine particles.

However, when the aperture diameter is reduced to approximately 25 micrometers or less in order to measure particles of, for example, 1 micrometer in diameter, vibration from a drive source within the apparatus, such as a fan, syringe pump and the like, propagates to the particle detection device and becomes noise that is difficult to distinguish from the weak signal from the particle.

### SUMMARY OF THE INVENTION

The scope of the invention is defined solely by the appended claims, and is not affected to any degree by the statements within this summary.

A first aspect of present invention is a particle measuring apparatus comprising: a detection device with an aperture through which pass particles contained in a particle suspension liquid, for detecting a signal generated when a particle passes through the aperture; and a detection device supporting part comprising an elastic body, for supporting the detection device through the elastic body.

A second aspect of present invention is a particle measuring apparatus, comprising: a detection device with an aperture through which passes particles contained in a particle suspension liquid; a detection device supporting part comprising an elastic body, for supporting the detection device through the elastic body; electrodes for applying a voltage to the particle suspension liquid; and a signal obtainer for obtaining signals based on the change in electrical resistance when a particle contained in the particle suspension liquid passes through the aperture.

A third aspect of the present invention is a particle measuring apparatus comprising: a detection device through which particles can internally pass through; a detection device supporting part comprising an elastic body, for supporting the detection device through the elastic body; and a signal obtainer for obtaining signals from particles passing through the interior of the detection device.

A fourth aspect of the present invention is a particle measuring apparatus comprising: a detection device with an aperture through which passes particles contained in a particle suspension liquid; and a detection device supporting part comprising a vibration absorbing member, for supporting the detection device through the vibration absorbing member.

### BRIEF DESCRIPTION OF THE DRAWINGS

FIG. 1 is a perspective view of an embodiment of the particle diameter measuring apparatus of the present invention;

FIG. 2 is a fluid circuit diagram and block diagram of the particle diameter measuring apparatus of FIG. 1;

FIG. 3 is a perspective view of a detection device;

FIG. 4 is a perspective view of the detection device including a partial cross section;

FIG. 5 is a front view of the detection device including a partial cross section;

FIG. 6 is a bottom view of the detection device;

FIG. 7 is a top view of a mounting fixture;

FIG. 8 is a front view of the mounting fixture;

FIG. 9 is a side view of the mounting fixture;

FIG. 10 is a cross sectional view on the A-A line of FIG. 9;

FIG. 11 is a cross sectional view on the B-B line of FIG. 9;

FIG. 12 is a top view of a tube adapter;

FIG. 13 is a side view of the tube adapter;

FIG. 14 is a cross sectional view on the C-C line of FIG. 13;

FIG. 15 is a perspective view of a buffer;

FIG. 16 is a top view of a top plate;

FIG. 17 is a perspective view of a connector piece;

FIG. 18 is a top view of a bottom plate;

FIG. 19 is a top view of a foam elastic body;

FIG. 20 shows a grip piece; (a) is a top view, (b) is a side view, (c) is a cross sectional view on the D-D line;

FIG. 21 is a perspective view of the detection device including a partial cross section;

FIG. 22 is a front view of the detection device including a partial cross section;

FIG. 23 is a bottom view of the detection device;

FIG. 24 shows a baseline waveform when a 250 Hz sound is generated;

FIG. 25 shows a baseline waveform when a 4000 Hz sound is generated;

FIG. 26 shows a baseline waveform when a 1,000 Hz sound is generated; and

FIG. 27 illustrates another example of a lockmechanism.

### DETAILED DESCRIPTION OF THE PREFERRED EMBODIMENTS

Hereinafter, an embodiment of the particle diameter measuring apparatus of the present invention will be described in detail with reference to the accompanying drawings.

### [Particle Diameter Measuring Apparatus]

The general structure of the particle diameter measuring apparatus is first described below.

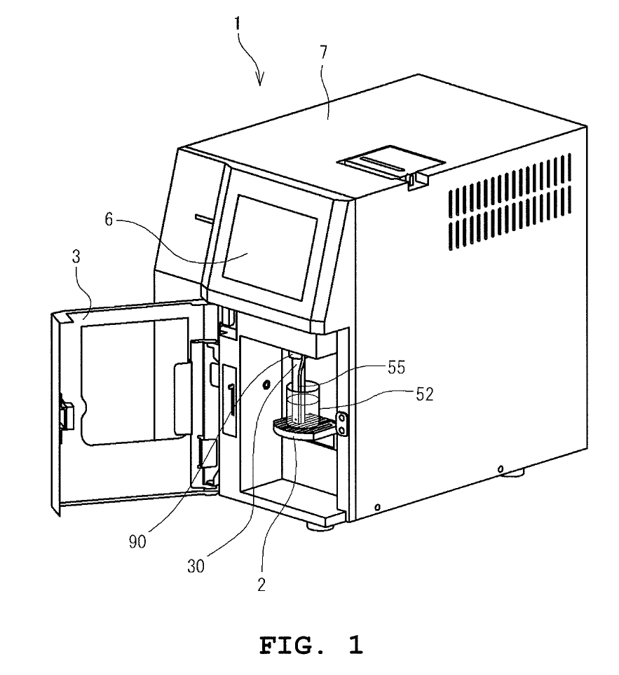

FIG. 1 is a perspective view of the particle diameter measuring apparatus 1 of the first embodiment.

The particle diameter measuring apparatus 1 is a particle analyzer of the electrical resistance type for measuring the size and number of particles based on the change in electrical resistance when a particle suspension liquid containing particles such as cells, toner or the like flows through a aperture and a particle in the suspension passes through the aperture. FIG. 1 shows a door 3 on the front side of a container platform 2 in an open state to allow the placement of a beaker 52, which is a container accommodating a particle suspension liquid. The container platform 2 is vertically movable so that when the beaker 52 containing the particle suspension liquid is placed on the platform 2, the container platform 2 moves to a bottom position and a detection device 10 is arranged within the beaker 52, and thereafter the container platform 2 is moved to a top position.

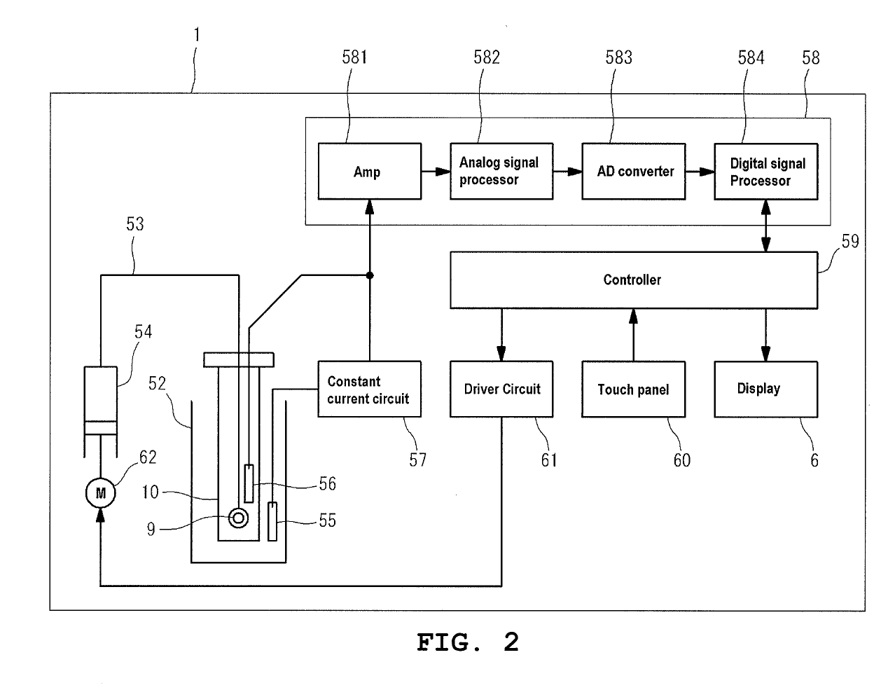

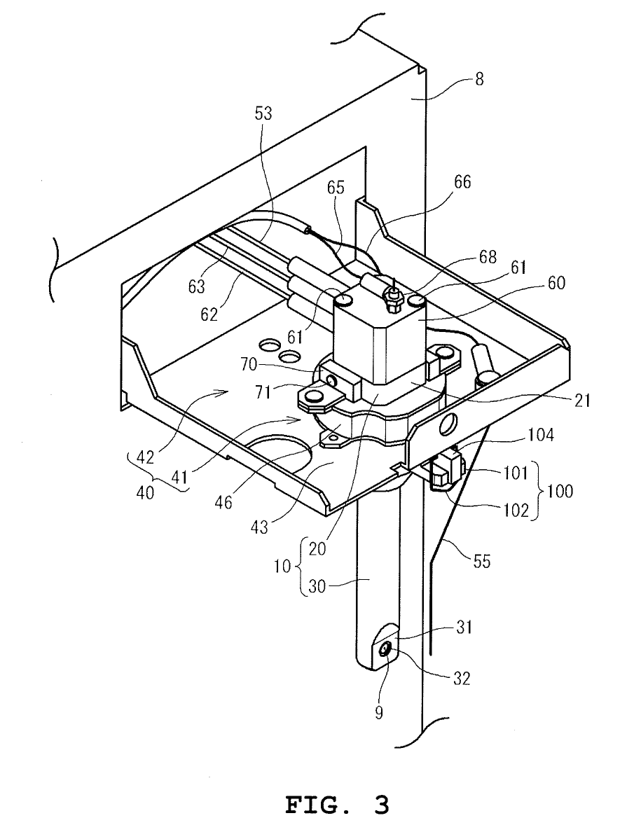

As shown in FIGS. 2 and 3, the particle diameter measuring apparatus 1 is mainly configured by a detection device 10 provided with an aperture 9 for the passage of a particle suspension liquid, detection device supporting part 40 for supporting the detection device 10, syringe pump 54 for aspirating the particle suspension liquid through the aperture 9 of the detection device 10, waveform signal processor 58 for processing the waveform of the signal obtained when a particles passes through the aperture 9, controller 59 configured by a CPU and memory and the like, display unit 6, and touch panel 60 provided on the front surface of the display unit 6. These components may be installed or accommodated within a box-like casing 7.

The structure of the various components is described below according to the flow of the measurement series.

As shown in FIG. 1, the measurement starts when the detection device 10 is arranged within the beaker 52 and the operator inputs a measurement start instruction on the touch panel 60. When the measurement starts, the controller 59 sends an instruction signal for the aspiration of the preparation to a drive circuit 61. The drive circuit 61 drive a stepping motor 62 based on the received instruction signal. The syringe pump 54 is driven by the stepping motor 62 and aspirates the particle suspension liquid within the beaker 52 through the detection device 10 and a particle suspension aspirating tube 53.

The particle diameter measuring apparatus 1 is provided with a first electrode (negative electrode) 55 disposed within the beaker 52 and outside of the detection device 10, second electrode (positive electrode) 56 disposed within the detection device 10, and a constant current circuit 57 for providing a constant current between the first electrode 55 and second electrode 56. The constant current circuit 57 applies a voltage between the electrodes so that a constant current flows to the first and second electrodes at the same time the syringe pump 54 aspirates the particle suspension liquid. When a particle passes through the aperture 9 of the detection device 10, there is a change in the electrical resistance between the first electrode 55 and second electrode 56, and the current representing this change of electrical resistance is input to the waveform signal processor 58.

The waveform signal processor 58 is provided with an amp 581, analog signal processing unit 582, AD converter 583, and digital signal processing unit 584. When a current representing a change in the electrical resistance is input, the amp 581 converts the input current to a voltage, and generates an analog signal, which is output to the analog signal processing unit 582. The analog signal processing unit 582 amplifies and filters the analog signal received from the amp 581 to obtain a signal suited for output to the AD converter 583, which is described later. The AD converter 583 samples the received analog signal for a waveform corresponding to 1 particle, and converts the signal to a digital signal, which is output to the digital signal processing unit 584. The digital signal processing unit 584 extracts characteristic data from the pulse signal corresponding to one particle contained in the received digital signal. The characteristic data, for example, includes pulse height and pulse width. The digital signal processing unit 584 generates histogram data based on the characteristic data of a plurality if particles and stores the data in memory, and also sends the histogram data to the controller 59. The digital signal processing unit 584 counts the number of particles based on the number of received digital signals, and sends the particle count to the controller 59. The controller 59 analyzes the particle diameter, volume, and concentration in the particle suspension liquid from the characteristic data received from the digital signal processing unit 584. The controller 59 performs statistical analysis based on average particle diameter, standard deviation and the like, and displays the analysis results and particle count on the display unit 6.

### [Detection Device]

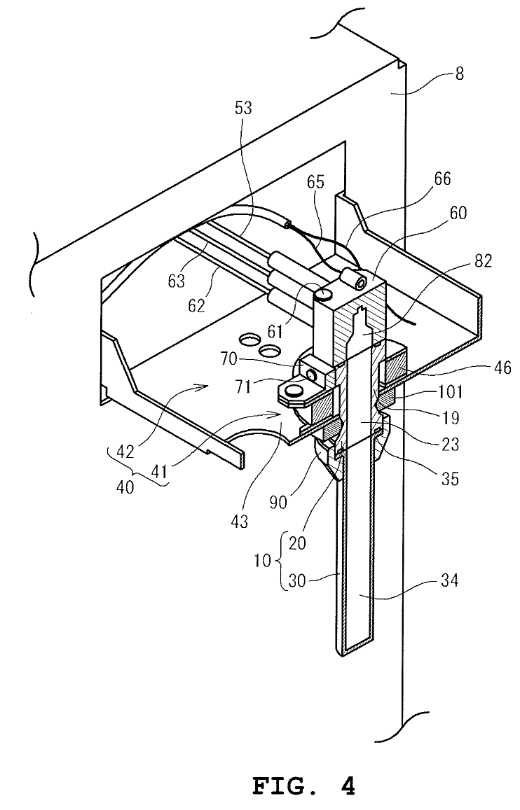

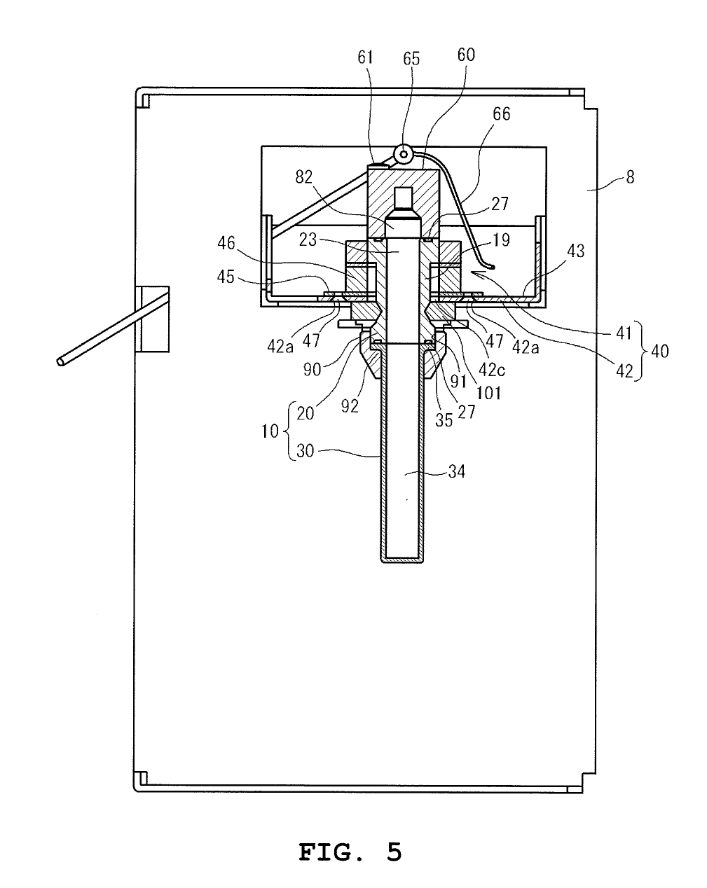

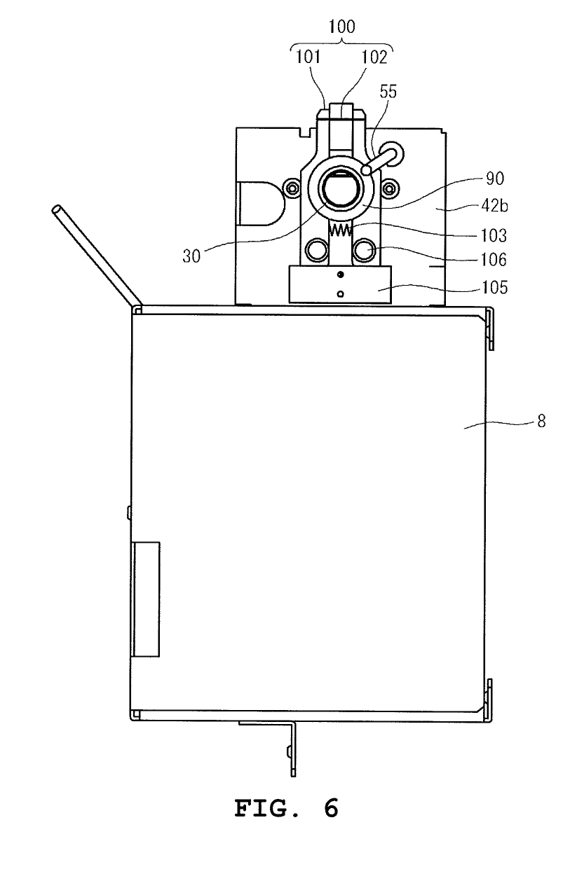

The detection device 10 is described in detail below. FIG. 3 is a perspective view of the detection device 10 of the particle diameter measuring apparatus 1 showing the detection device 10 being supported by a detection device supporting part 40, which is described later. FIG. 4 is a perspective view of the detection device 10 including a partial cross section. FIG. 5 is a front view of the detection device 10 including a partial cross section. FIG. 6 is a bottom view of the detection device 10. Note that, in FIGS. 3 through 6, and FIGS. 21 through 23 which are described later, the detection device supporting part 40 for supporting the detection device 10 and a casing 8 within which the detection device supporting part 40 is arranged are both described in terms of the detection device 10 installed in the apparatus. The casing 8 is arranged within the casing 7 on the outer side of the mentioned particle diameter measuring apparatus 7.

The detection device 10 is mainly configured by a mounting fixture 20, and a detection body 30 removably mounted to the bottom end of the mounting fixture 20. The detection device 10 is supported by the detection device supporting part 40 via the mounting fixture 20.

As shown in FIGS. 3 through 5, the detection body 30 is configured by a tubular member that is closed at one end (the bottom end while in use as shown in the drawing), and a ruby pellet 32 is disposed in a concavity 31 in the vicinity of the bottom end. An aperture 9 for the passage of the particle suspension liquid containing particles is disposed in the center of the pellet 32. The interior of the detection device 10 forms a first flow path 34; the first flow path 34 connects to a second flow path 23 (refer to FIG. 4) of the mounting fixture 20 which is described later.

A collar 35 is formed at the top end of the detection body 30. As will be described below, the detection body 30 is connected to the mounting fixture 20 by fitting the installation ring 90 (refer to FIGS. 4 and 5) in the detection body 30 so that the collar 35 is supported from below, such that the installation ring 90 is mounted on the mounting fixture 20. The detection body 30, for example, can be made of glass, ABS resin or the like.

The detection body 30 must be exchanged in accordance with the detection target particle since the diameter of the aperture 9 must change according to the size of the detection target particle. In the electrical resistance type particle diameter measuring apparatus 1 of the present embodiment, it is possible to detect particles of approximately 2 to 60% of particle diameters via the diameter of the aperture 9. Therefore, in the particle diameter measuring apparatus 1, the detection body which has an aperture diameter of 25 micrometers is used when the detection target particle diameter is 0.5 to 15 micrometers. The detection body which has an aperture diameter of 50 micrometers is used when the detection target particle diameter is 1 to 30 micrometers. The detection body which has an aperture diameter of 100 micrometers is used when the detection target particle diameter is 2 to 60 micrometers. The detection body which has an aperture diameter of 200 micrometers is used when the detection target particle diameter is 4 to 120 micrometers.

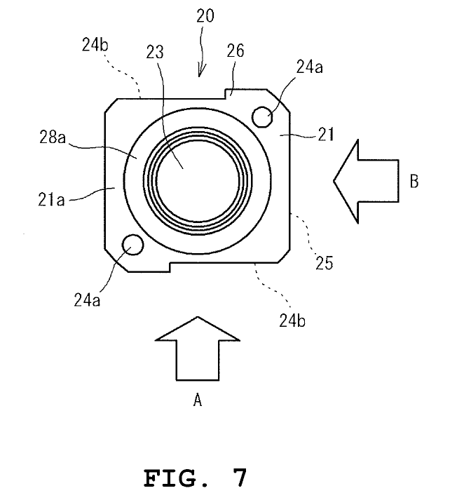

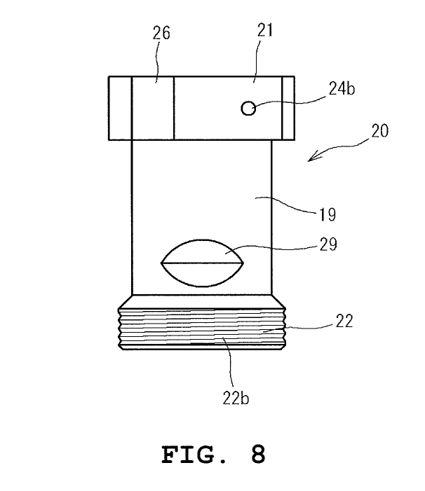

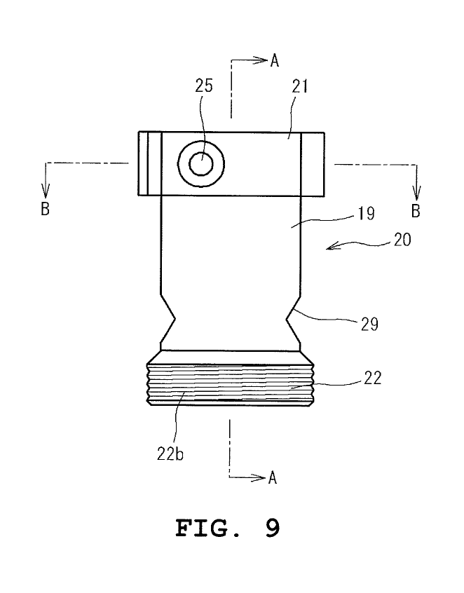

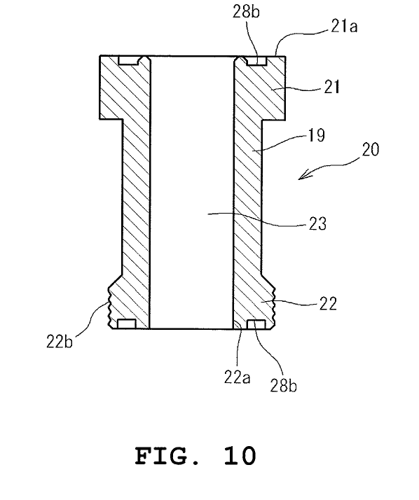

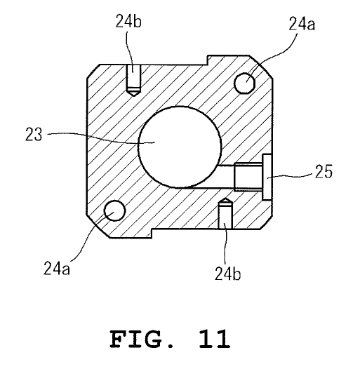

The mounting fixture 20 is described below. FIG. 7 is a top plan view of the mounting fixture 20, FIG. 8 is a front view of mounting fixture 20 (viewed from the arrow A direction of FIG. 7), FIG. 9 is a side view of the mounting fixture 20 (viewed from the arrow B direction of FIG. 7), FIG. 10 is a cross sectional view on the A-A line of FIG. 9, and FIG. 11 is a cross sectional view on the B-B line of FIG. 9.

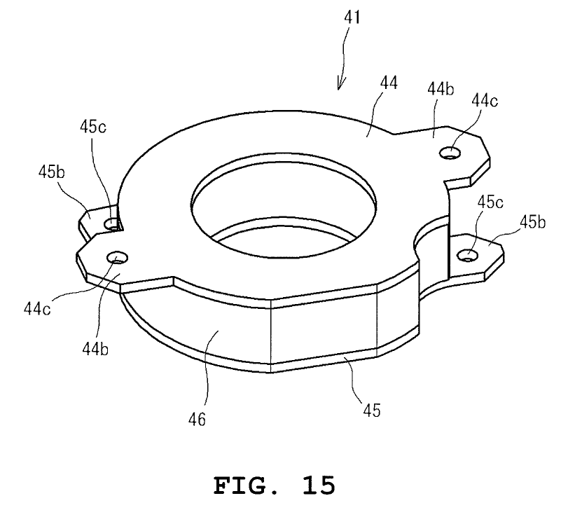

The mounting fixture 20 is mainly a component for mounting the replaceable component of the detection body 30 to the detection device supporting part 40 of the particle diameter measuring apparatus 1. As shown in FIGS. 8 through 10, the mounting fixture 20 is a short tube. A protrusion (flange) 21 is provided on the top end of the mounting fixture 20 in the longitudinal direction. The flange 21 has a collar shape that protrudes laterally, and has an external diameter that is large compared to the barrel 19 in the center of the longitudinal direction of the mounting fixture 20. The detection device 10 is supported by the detection device supporting part 40 through the flange 21. As will be described later, the detection device supporting part 40 incorporates a buffer 41 (refer to FIG. 15) including a foam elastic body 46, and the buffer 41 also includes a top plate 44 that sits on top of the foam elastic body 46. The flange 21 is mounted on the top plate 44, and the barrel 19 of the mounting fixture 20 is inserted into an opening 44a provided in the top plate 44, as shown in FIG. 2.

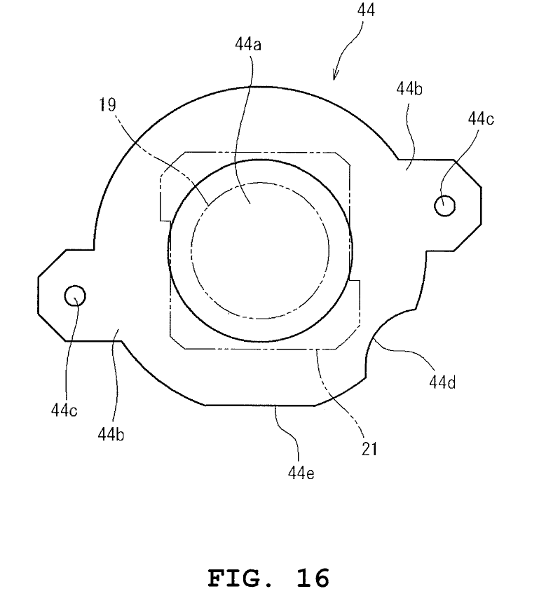

The function of the mounting fixture 20 is described below with reference to FIG. 16. In FIG. 16, the single dash line represents the planar shape of the flange 21 of the mounting fixture 20, and the double dash line represents the horizontal cross sectional shape of the barrel 19 of the mounting fixture 20. As shown in FIG. 16, the flange 21 is sized to protrude from the opening 44a of the buffer 41 when the flange 21 is seated on the top plate 44 of the buffer 41 with the barrel 19 inserted in the opening 44a. More specifically, the four corners protrude from the opening 44a when the barrel 19 of the mounting fixture 20 has been inserted in the opening 44a. Thus, the flange 21 can be latched to the top plate 44, and the detection device 10 is supported so as to hang perpendicularly from the top plate 44 via its own weight. Referring again to FIGS. 7 through 117˜11, the structure of each part of the mounting fixture 20 is described below.

The mounting fixture 20 includes the flange 21 disposed at the top thereof, the mounting part 22 disposed at the bottom, and a second flow path 23 disposed within. As shown in FIG. 7, the flange 21 is flat and approximately square. Screw holes 24a are provided at two opposed corners so that the second flow path 23 is situated therebetween in the center of the flange 21, the screw hole 24a being configured by a through hole for the insertion of a screw 61 (refer to FIG. 3) for connecting the tube adapter 60 (refer to FIGS. 3 through 5).

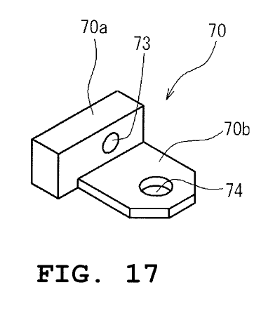

As indicated by the dashed lines in FIG. 7, screw holes 24b (refer to FIG. 8) are formed on the side surface of the flange 21 in the vicinity of the remaining two opposed corners with the center second flow path 23 interposed therebetween, the screw holes 24b being provided for the insertion of screws 71 for anchoring, to the flange 21, the connecting piece 70 (refer to FIGS. 3, 4, and 17) used to anchor the flange 21 to the detection device supporting part 40 (refer to FIGS. 3 and 4). The screw hole 24a is formed in a vertical direction (longitudinal direction of the mounting fixture 20), whereas the screw hole 24b is formed in a horizontal direction (direction perpendicular to the longitudinal direction of the mounting fixture 20). A step 26 is also formed on the side surface on which the screw hole 24b is provided. The connecting piece 70 (to be described later) is positioned so as to communicate with the screw hole 24b and through hole 73 (refer to FIG. 17) of the connecting piece 70 via a vertical piece 70a (refer to FIG. 17) abutting the step 26.

As shown in FIG. 9, the flange 21 is provided with a washing liquid supply port 25 that connects to a washing liquid tube 62 for supplying washing liquid into the detection device 10 to wash the flow path of the detection device 10. The washing liquid supply port 25 communicates with the second flow path 23, as shown in FIG. 11.

As shown in FIG. 10, a channel 28a for the disposition of an O-ring 27 is formed on the top surface 21a of the flange 21.

A male threaded part 22b for engaging a female threaded part 91 (refer to FIG. 5) of the installation ring 90 (described layer) is provided on the outer surface of the mounting part 22 disposed on the bottom of the mounting fixture 20. A channel 28b for the disposition of an O-ring 27 is formed on the bottom surface 22a of the mounting part 22.

A channel 29 which has an approximate V-shaped cross section, as shown in FIGS. 8 and 9, is formed at locations from the mounting part 22 on the outer surface of the barrel 19 between the flange 21 and mounting part 22. The channel 29 is formed at two symmetrical locations on the side surface centered on the second flow path 23. As shown in FIG. 8, the channel 29 is provided in the horizontal direction (a direction perpendicular to the longitudinal direction of the mounting fixture 20). The two channels 29 are mutually parallel in disposition. Using the channels 29, the mounting fixture 20 can be anchored (prevented from moving, including rotation) when the detection body 3 is installed on the mounting fixture 20 and removed from the mounting fixture 20.

### [Installation Ring]

In the present embodiment, the detection body 30 and the mounting fixture 20 are connected via the installation ring 90.

As shown in FIGS. 4 and 5, the installation ring 90 is a short tubular member, the top interior surface of which is provided with a female threaded part 91 capable of engaging the previously mentioned male threaded part 22b disposed on the outer surface of the mounting part 22 of the mounting fixture 20. The interior of the installation ring 90 is provided with a latch 92 configured by a step formed to engage the diameter intermediate to the top opening and bottom opening. The latch 92 latches to the bottom surface of the previously mentioned collar 35 of the detection body 30.

The bottom outer side of the installation ring 90 is tapered with a decreasing diameter toward the tip (bottom end). The outer surface of the installation ring 90 is preferably grooved to be grasped easily when screwing or unscrewing the male threaded part 91 and female threaded part 22b of the mounting part 22.

The top opening of the installation ring 90 is large enough to allow passage of the collar 35 of the detection body 30, whereas the bottom opening of the installation ring 90 is not large enough to allow passage of the collar 35 but is large enough for the passage of the tubular part 30a of the detection body 30.

The mounting of the detection body 30 on the mounting fixture 20 is performed as follows.

First, the closed end (end on the side on which the pellet 32 with the aperture is disposed) of the detection body 30 provided with an aperture 9 of a desired diameter is inserted toward the bottom opening from the top opening of the installation ring 90.

The detection body 30 is fitted to the mounting fixture 20 so that there is contact between the top end surface (top surface of the collar 35) of the detection body 30 and the bottom end surface of the mounting fixture 20, and the female threaded part 91 of the installation ring 90 is screwed onto the male threaded part 22b of the mounting fixture 20. The collar 35 of the detection body 30 is anchored by the latch 92 of the installation ring 90 and the mounting part 22 of the mounting fixture 20. Thus, the detection body 30 is mounted on the mounting fixture 20. The detection body 30 can be readily installed on the mounting fixture 20 and easily removed from the mounting fixture 20 because the mounting part 22 of the mounting fixture 20 protrudes downward from the opening of the base as will be described later.

Thus, the detection body 30 can be simply connected to the mounting fixture 20. Note that, in the present embodiment, although a locking mechanism is provided to prevent operation of the mounting fixture 20 when engaged, details of the locking mechanism are described later.

When removing the detection body 30 from the mounting fixture 20, the installation ring 90 is rotated in the reverse direction to disengage the engagement of the female threaded part 91 of the installation ring 90 and the male threaded part 22b of the mounting part 22. Thus, the detection body 30 can be removed from the mounting fixture 20 with the collar 35 latched to the latch 42 of the installation ring 90 so as to avoid the danger of the detection body 30 falling.

### [Tube Adapter]

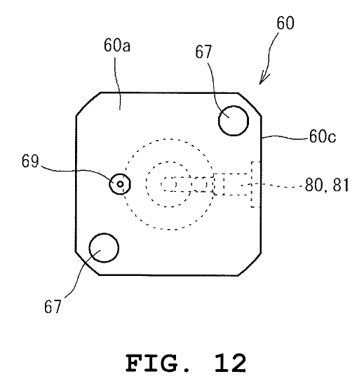

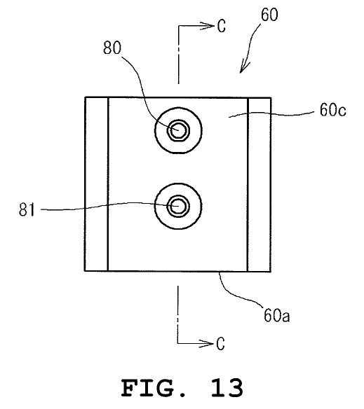

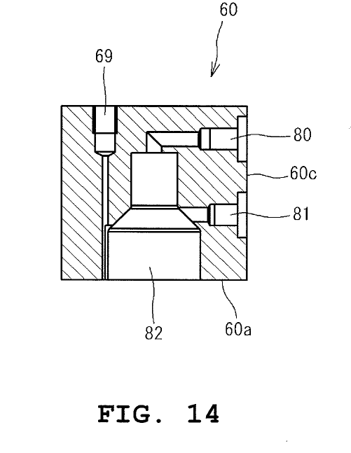

The tube adapter 60 is described in detail below. FIG. 12 is a top view of the tube adapter 60, FIG. 13 is a side view of the tube adapter 60, and FIG. 14 is a cross sectional view on the C-C line of FIG. 13.

The tube adapter 60 is an approximately cube shape member. The bottom surface 60a is open. As shown in FIG. 12, the opposed corners are provided with through holes 67 for the insertion of a screw 61 for anchoring the tube adapter 60 to the flange 21 of the mounting fixture 20. The tube adapter 60 is anchored to the flange 21 by screwing the screw 61 inserted in the through hole 67 into the screw hole 24 formed in the top surface of the flange 21. The top surface 60a of the tube adapter 60 is provided with a hole 69 for the disposition of a connector 68 (refer to FIG. 3) used to connect the wire 65 and a lead (not shown in the drawings) from the first electrode 55 within the detection device 10.

The side surface (side surface of the inner side of the mechanism when the tube adapter 60 is locked to the flange 21) 60c of the tube adapter 60 is provided with a washing liquid aspirating port 81 connected to the tube 63 for aspirating the washing liquid and a particle suspension liquid aspirating port 80 connected to a suspension liquid aspirating tube 53 for aspirating the particle suspension liquid.

The suspension liquid aspirating port 80 and washing liquid aspirating port 81 communicate with the internal space 82 of the tube adapter 60 (refer to FIG. 14), and the internal space 82 communicates with the internal space of the detection device 10, that is, the flow path configured by the first flow path 34 and second flow path 23, as shown in FIGS. 4 and 5.

The tube adapter 60 and mounting fixture 20, and the detection body 30 and mounting part 22 of the mounting fixture 20 are respectively connected via the respective O-ring 27 so as to be liquid-tight.

### [Detection Device Supporting Part]

The detection device supporting part 40 is described in detail below.

The detection device supporting part 40 supports the detection device 10 at a predetermined position within the apparatus, that is, supports the detection device 10 at a measurement position for aspirating the particle suspension liquid within the detection device 10 and detecting particles. As shown in FIG. 3, the detection device supporting part 40 is provided with a buffer 41 (refer to FIG. 16) that includes a foam elastic body 46, and a base 42. The base 42 has an opening 42c (refer to FIG. 5) large enough for the passage of the mounting part 22 of the mounting fixture 20 and the surface 43 on which the buffer 41 is seated, and is anchored to the casing 8 of the particle detection unit.

FIG. 15 is a perspective view of the buffer 41. The buffer 41 is configured by a top plate 44, bottom plate 45, and the foam elastic body 46 disposed medially to the top plate 44 and bottom plate 45. The foam elastic body 46 is adhered to the top plate 44 and bottom plate 45 with adhesive.

The top plate 44 is an annular flat member having an opening 44a in the center of sufficient size for the passage of the mounting part 22 of the mounting fixture 20, and has a thickness of approximately 1.5 mm, as shown in FIG. 16. The plate material is not specifically limited, but is preferably aluminum from the perspective of being light weight. When the top plate 44 is made of lightweight aluminum, the foam material of the foam elastic body 46 is not crushed and there is no reduction of the damping effect of the foam elastic body 46. The protrusions 44b extending from the outer diameter direction are provided at opposed positions with the opening 44a between on the top plate 44a, and a threaded hole 44c is formed on the protrusion 44b. The threaded hole 44c is used to anchor the mounting fixture 20 to the top plate 44 using the connection piece 70. The connection piece 70 is configured by two pieces joined to form an L-shaped cross section, with the vertical piece 70a abutting the flange 21 of the mounting fixture 20, and the horizontal piece 70b abutting the top plate 44, as shown in FIG. 17. The vertical piece 70a is provided with a through hole 73 for the insertion of a screw, and the horizontal piece 70b is provided with a through hole 74 for the insertion of a screw. The flange 21 of the mounting fixture 20 is anchored to the top plate 44 by inserting a screw 71 through the through hole 73 of the vertical piece 70a and screwing into the side surface of the flange 21, and inserting a screw 72 through the through hole 74 of the horizontal piece 70b and screwing into the screw hole 44c of the top plate 44.

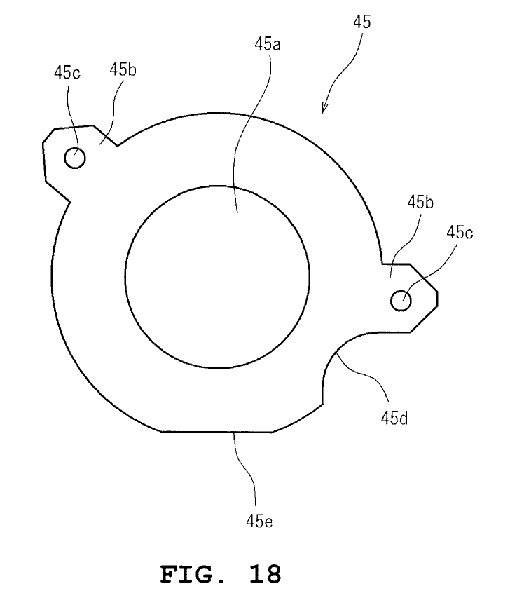

Similar to the top plate 44, the bottom plate 45 is an annular flat member having an opening 45a in the center of sufficient size for the passage of the mounting part 22 of the mounting fixture 20, and has a thickness of approximately 1.5 mm, as shown in FIG. 18. The plate material is not specifically limited, but is preferably aluminum from the perspective of being light weight. The protrusions 45b extending from the outer diameter direction are provided at opposed positions with the opening 45a between, and a threaded hole 45c is formed on the protrusion 44b. The threaded hole 45c is sued to anchor the bottom plate 45 to the base 42. As shown in FIG. 5, the base 42 is provided with a hole 42a corresponding to the threaded hole 45c of the bottom plate 45 seated on the base 42, such that the bottom plate 45 is anchored to the base 42 by inserting a screw 47 into the hole 42a via the bottom surface of the base 42 and screwing into the threaded hole 45c of the bottom plate 45.

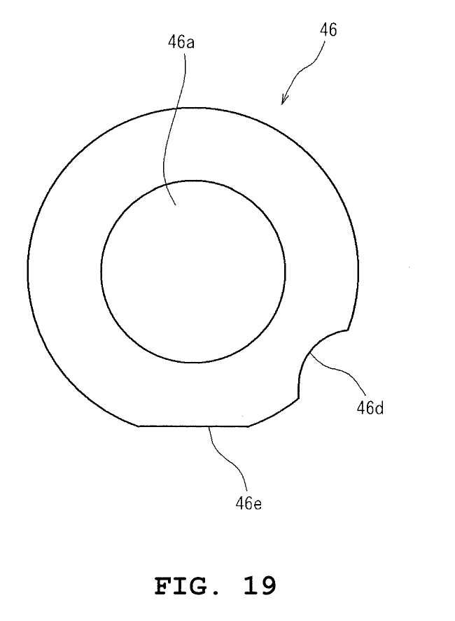

The foam elastic body 46 is an annular member with a central opening 46a, and has a thickness of approximately 1 to 10 mm, and preferably 3 to 7 mm, as shown in FIG. 19. In the present embodiment, the thickness of the foam elastic body 46 is 5 mm. The foam elastic body 46 is a member preventing the transmission of vibration from the drive sources of the fan, syringe pump and the like within the apparatus, and vibration from outside the apparatus (including vibration generated by the propagation of sound waves to the apparatus casing from conversation among technicians around the apparatus) to the detection device 10.

The material of the foam elastic body 46 may be a porous material with elasticity (foam), such as, for example, semi-independent semi-continuous foam of ethylene propylene diene monomer (EPDM) and polyurethane foam. An example of semi-independent semi-continuous foam EPDM is EPT-SEALER series (commercial name; Nitto Denko Corporation), and an example of polyurethane foam is Calmflex series (commercial name; INOAC Foam Company). Note that a spring may used used rather than a foam elastic body insofar as the spring blocks the transmission of vibration to the detection device. The spring used may be a coil spring, plate spring or the like. As a result of investigations by the present inventors, it has been confirmed that using polyurethane foam and semi-independent and semi-continuous foam effectively eliminates generation of noise caused by vibration, and allows signals from particles to be distinguished from noise.

### [Lock Mechanism]

In the present embodiment, the detection device 10 is supported by the buffer 41 of the detection device supporting part 40. More specifically, the flange 21 of the mounting fixture 20 of the detection device 10 is anchored to the top plate 44 configuring the buffer 41 via the connecting piece 70, and the bottom plate 45 configuring the buffer 41 is anchored to the base 42 of the detection device supporting part 40. The foam elastic body 46 is disposed between the top plate 44 and the bottom plate 45. The detection device supporting part 40 therefore supports the flange 21 of the detection device 10 through the foam elastic body 46. More specifically, the detection device supporting part 40 supportively floats the detection device 10 from the base 42 via the foam elastic body 46. Viewed from the detection device 10, the detection device 10 is supported by the detection device supporting part 40 that includes the foam elastic body 46 through the flange 21.

Supporting the detection device 10 on the detection device supporting part 40 through the flange 21 alone means the detection device 10 does not contact the detection device supporting part 40 unless through the flange 21. Insofar as the detection device 10 is not anchored by the lock mechanism 100 (to be described later), the detection device 10 does not contact the base 42 except through the flange 21 since the detection device 10 is supportively floated from the base 42 by the flange 21 seated on the buffer 41 of the detection device supporting part 40. Therefore, vibration propagated to the base 42 from the drive sources such as the syringe pump 54 and stepping motor 64 (refer to FIG. 2) of the particle diameter measuring apparatus 1 is invariably transmitted to the detection device 10 intermediated by the foam elastic body 46 of the buffer 41. The vibration transmitted to the detection device 10 is thus blocked by the foam elastic body 46, and virtually none of the vibration from the drive sources is propagated to the detection device 10.

As previously described, the foam elastic body 46 effectively prevents transmission to the detection device 10 of the vibration generated within the apparatus and the vibration transmitted to the apparatus from outside the apparatus due to the high capacity for damping vibration transmission. As a result, it is possible to prevent noise caused by such vibration, signals generated by the passage of microparticles can be readily distinguished from noise, and particle measurement accuracy is thereby improved.

On the other hand, although the installation ring 90 must be rotated when installing the detection body 30 on the mounting fixture 20 or the removing from the mounting fixture 20, the mounting fixture 20 is moved relatively simply with little force since the flange 21 of the mounting fixture 20 is supported only by the soft part of the foam elastic body 46. Therefore, some effort must be expended in the operation to rotate the installation ring 90 while the fingers press the mounting fixture 20 so that the mounting fixture 20 will not move. When the installation ring 90 is rotated without anchoring the mounting fixture 20, a shearing force acts on the foam elastic body 46 and may cause the foam elastic body 46 to separate from the plates 44 and 45 and lead to ultimate damage.

In the present embodiment, therefore, the lock mechanism 100 is used to anchor the mounting fixture 20 of the detection device 10 when installing or removing the detection body 30.

The lock mechanism 100 is provided on the back surface 42b of the surface 43 of the base 42 of the detection device supporting part 40. As shown in FIGS. 3 through 6, the lock mechanism 100 mainly provides a pair of clamps 101 capable of gripping the mounting fixture 20, and a ring body 102 which is a locking tool for locking the two clamps 101 while the clamps 101 are gripping the mounting fixture 20. The lock mechanism 100 further provides a spring 103 for pressing both clamps 101 in mutually opposite directions, positioning block 104 (refer to FIG. 3) for positioning when the grips are proximate to one another, and stopper 105 for regulating the separation position of the clamps 101.

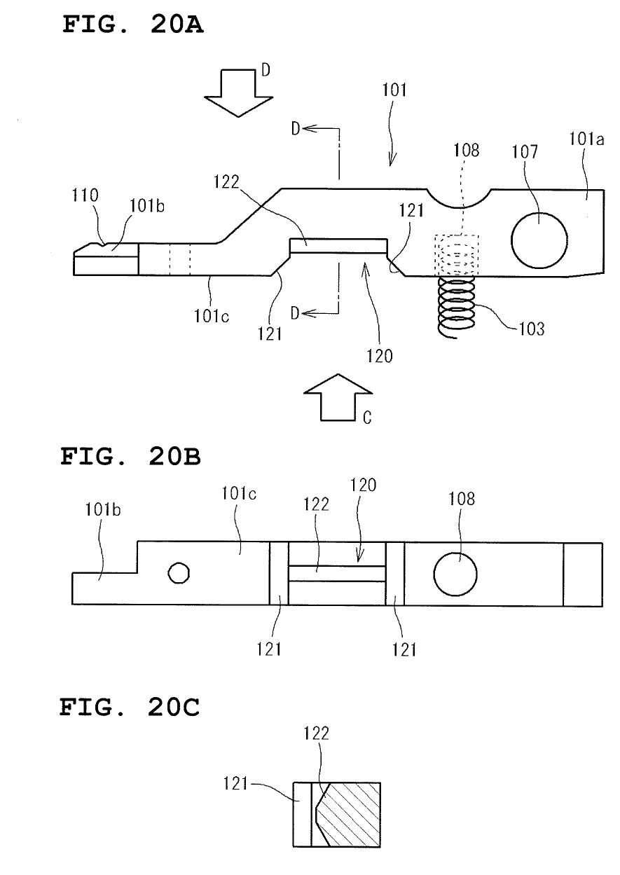

FIG. 20 shows the clamps 101, (a) in top view, (b) in side view (from the arrow C direction of FIG. 20(a)), and (c) in cross sectional view on the D-D line. In the following description, only one of the pair of clamps 101 is mentioned. In the present embodiment, the two identically configured clamps 101 are disposed so as to be opposed as shown in FIG. 6.

In the following description, the end on the side provided with the through hole 107 (side indicated by the arrow D in FIG. 20) is referred to as the base end, and the end on the side provided with the latch channel 110 for fitting the lock ring 102 (side indicated by the arrow E in FIG. 20) is referred to as the tip end. The side surface on the side opposite the two clamps 101 engaging the lock 20 (side in the arrow D direction in FIG. 20) is referred to as the inside surface, and the side surface on the back side of the inside surface (side in the arrow E direction in FIG. 20) is referred to as the outside surface.

The clamp 101 is an elongated member having a certain thickness, the base end of which is provided with a through hole 107 for the insertion of a pin 106 (refer to FIG. 6). The clamp 101 is mounted on the back surface 42b of the base 42 so as to be rotatable. A hole 108 is formed from the through hole 107 in the inside surface of the tip end side, and an end of a spring 103 is disposed inside this hole 108. Both clamps 101 are pressed in a direction to cause mutual separation of the tips 101b on the tip ends thereof by the elastic force in the expansion direction of the spring 103, and the movement of the clamps 101 is regulated by the stopper 105 disposed on the base end from the pin 106 so that the movement does not exceed a predetermined range.

A notch-like pinch-grip 120 is formed approximately intermediate to the inside surfaces 101c of the clamps 101. The pinch-grip 120 includes two inclinations 121 that incline from the inside surface toward the outside surface, and a convexity 122 formed along the longitudinal direction between the two inclinations 121. As shown in FIG. 20(c), the convexity 122 has a height contracting toward the inside surface. The outside surface of the end 101b of the clamp 101 is provided with a lock channel 110 for locking the ring body 102.

As shown in FIG. 1, the positioning block 104 is anchored to the back surface 42b of the base 42 approximately intermediate to the tip ends 101b of the two clamps 101. The positioning block 104 is a member for positioning each clamp 101 essentially equidistant from and in proximity to the mounting fixture 20 with the mount position of the gripped mounting fixture 20 centered between the clamps 101 when the ends 101b of the clamps 101 are gripping and the clamps 101 are in mutual proximity, as shall be described later.

The positioning block 104 supports the lock tool of the ring body 102 so as to be freely oscillatable on the positioning block 104. The ring body 102 is a frame of bent wire, as shown in FIG. 3. The ends of the ring body 102 are an axis supported on the side surface of the positioning block 104, so as to be vertically rotatable as a pendulum.

### [Locking Operation and Unlocking Operation]

The mounting fixture 20 locking and unlocking operations using the lock mechanism 100 are described below.

FIGS. 3 through 6 show the mounting fixture 20 in the locked state via the lock mechanism 100. In this state, the detection body 30 is mounting on the mounting fixture 20 and removed from the mounting fixture 20. In this locked state, the pair of clamps 101 are positioned in mutual proximity and the end 101b abut the positioning block 104. The ring body 102 is fitted to the ends 101b of the clamps 101 so as to be mutually separated by the elastic force in the expansion direction of the spring 103.

In the locked state, the barrel 19 of the mounting fixture 20 is positioned between the opposed pinch-grips 120 of the clamps 101. Thus, the convexity 122 of the pinch-grip 120 is fitted in the channel 29 formed in the barrel 19, and the vertical (perpendicular direction) movement of the mounting fixture 20 is regulated. The inclination 121 formed on the tip end of the convexity 122 and the inclination 121 formed on the base end thereof abut the outer surface of the barrel 19, and the movement of the mounting fixture 20 in the forward and back directions (direction from the tip end toward the base end) is regulated. The mounting fixture 20 is therefore solidly anchored.

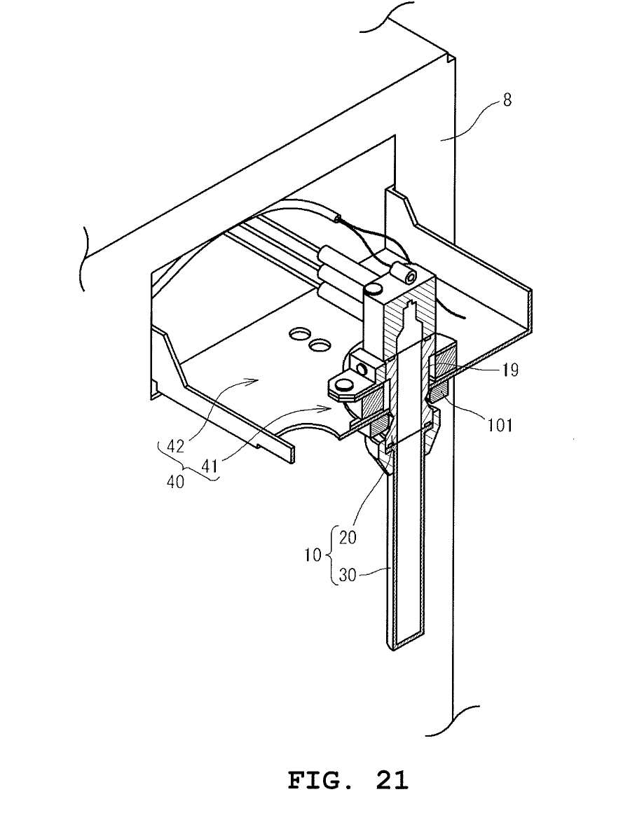

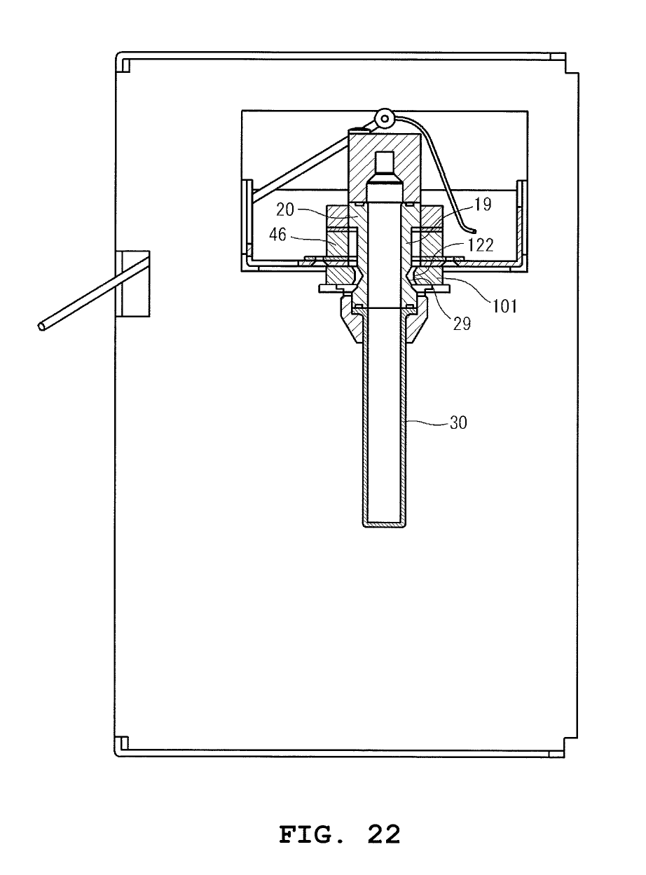

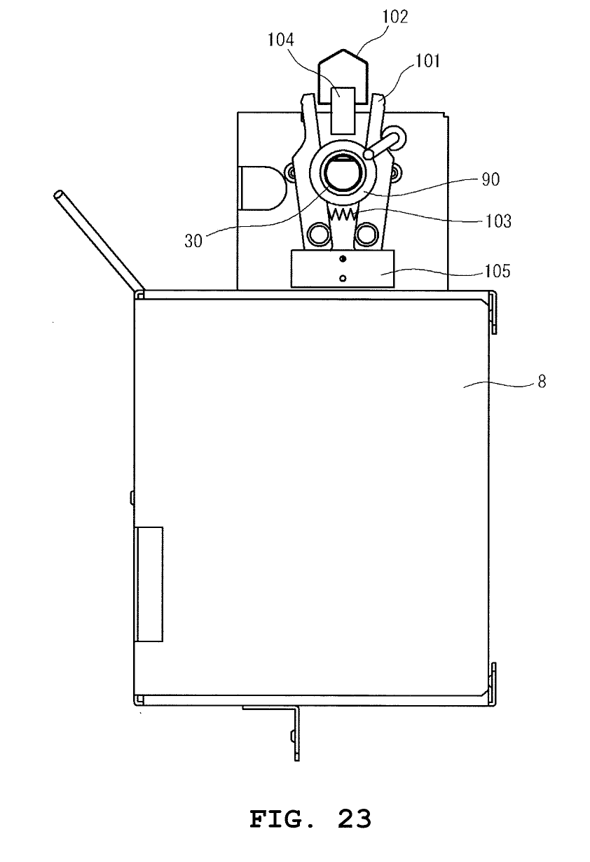

FIGS. 21 through 23 show the unlocked state of the mounting fixture 20 via the lock mechanism 100; FIG. 21 is a perspective view of the detection device with a partial cross section and corresponds to FIG. 4, FIG. 22 is a front view of the detection device with a partial cross section and corresponds to FIG. 5, and FIG. 23 is a bottom view of the detection device and corresponds to FIG. 6.

The lock release is accomplished simply by removing the ring body 102 from the channel 110 formed in the end 101b. That is, when the ring body 102 is removed from the channel 110, the clamps 101 move in the separation direction via the elastic force in the expansion direction of the spring 103. Then, since the convexity 120 of the clamps 101 also separate from the barrel 19, the contact between the outer surface of the barrel 19 and the inclination 121 of the clamp 101 is released as is the engagement between the convexity 122 and the channel 29.

In the present embodiment described above, vibration transmission to the detection device 10 is blocked by the mediation of the foam elastic body 46 in the path in which the vibration from the drive sources is propagated to the detection device 10. When the mounting device 20 is anchored to the detection device supporting part 40 by the lock mechanism 100, the vibration from the drive sources propagates to the detection device 10 through the lock mechanism 100, not just the foam elastic body 46. The vibration propagated through the lock mechanism 100 makes it difficult to distinguish the noise from the particle when measuring particle diameter in this state since the vibration propagates to the detection device 10 and is not blocked by the foam elastic body 46.

The particle diameter measuring apparatus of the present embodiment effectively eliminates noise caused by vibration by releasing the locked state of the lock mechanism 100 when measuring particle diameter (when particles are aspirated from the suspension liquid and pass through the aperture, and avoids the risk of damage to the foam elastic body 46 when replacing the detection device 10 by locking the mounting fixture 20 via the lock mechanism 100 when replacing the detection device 10.

### [Vibration Damping Effect]

In the present embodiment described above, blank measurements were performed when the detection device was supported by the foam elastic body alone (unlocked state in the examples), and when the detection device was anchored via the lock mechanism (locked state in a comparative examples), and the influence of noise generated during these measurements was investigated. The blank measurement was a measurement of a liquid preparation (blank preparation) that did not contain a suspension of particles, and was performed identically to the measurement of the particle suspension liquid. In the blank measurement, the particle count is ideally zero since only the baseline waveform signal is obtained, that is, only a waveform signal that does not contain a signal of a particle passing through the aperture is obtained. The particle count obtained by the blank measurement was made the index for evaluating the disruption of the base line, that is, the magnitude of the noise.

The signal waveforms obtained from the blank preparation was investigated using an oscilloscope with a detection device having an aperture diameter of 25 micrometers. Noise was generated during measurements as follows.

A speaker was placed at a position 150 mm from the door on the front surface of the apparatus, and sine waves were generated from the speakers at frequencies of 250, 400, and 1,000 Hz during measurements using sound generating software. Note that the volume of the sound was suitable for comparative investigation, and the evaluations of the examples and comparative examples were made using the same volume of sound at each frequency.

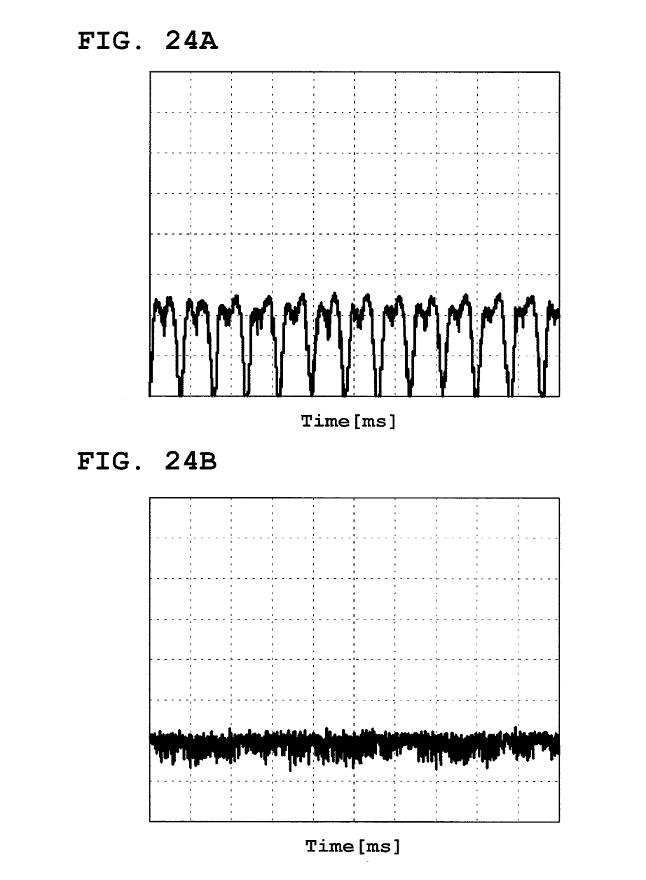

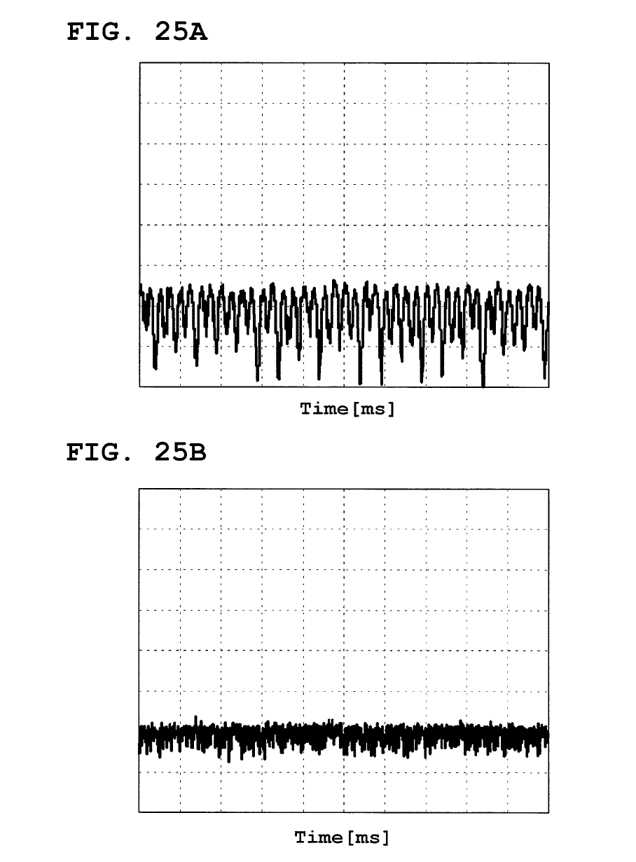

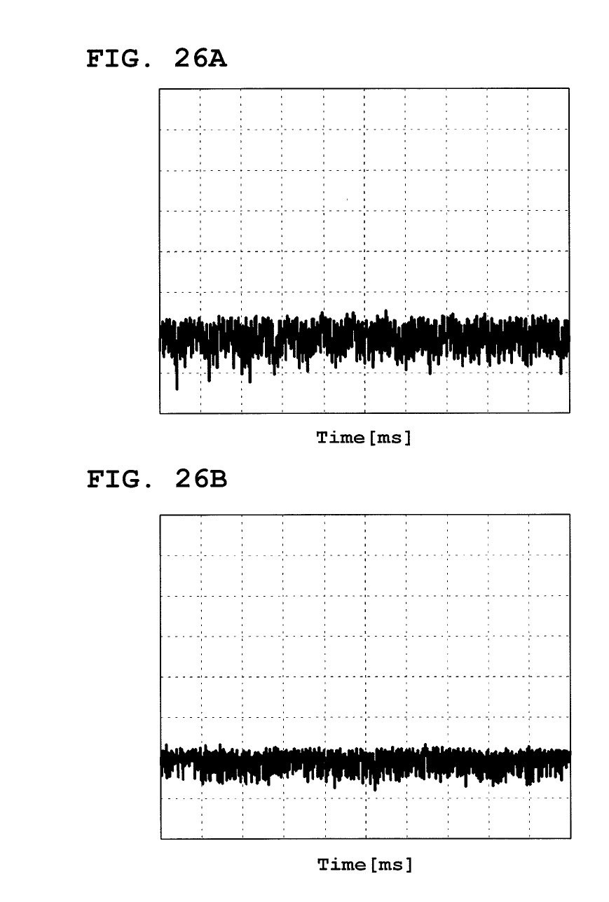

The results are shown in FIGS. 24 through 26. FIG. 24 shows the baseline waveform at a frequency of 250 Hz, FIG. 25 shows the baseline waveform at 400 Hz, and FIG. 26 shows the baseline waveform at 1,000 Hz. In the drawings, (a) shows the comparative example with the detection device locked, and (b) shows the example with the detection device unlocked.

As can be clearly understood from FIGS. 24(b), 25(b), and 26(b), when the detection device is locked, the baseline waveform is disrupted by the influence of the vibration caused by the generated sound, and the count increases in the blank measurement as shown in Table 1. Conversely, as can be understood from FIGS. 24(a), 25(a), and 26(a), when the detection device is unlocked, the baseline is stable and there is no observed increase of the count during the blank measurement as shown in Table 1.

Thus, reduction of the influence of noise on the measurement at an aperture diameter of 25 micrometers via the vibration damping by the foam elastic body was confirmed.

TABLE 1
Blank Measurement Counts

| | Frequency | | |
|---|---|---|---|
| | 250 Hz | 400 Hz | 1,000 Hz |
| Comparative Example | 20.494 | 29.007 | 19.061 |
| (detection device | | | |
| locked) | | | |
| Example (detection | 275 | 207 | 451 |
| device unlocked) | | | |

### [Modifications]

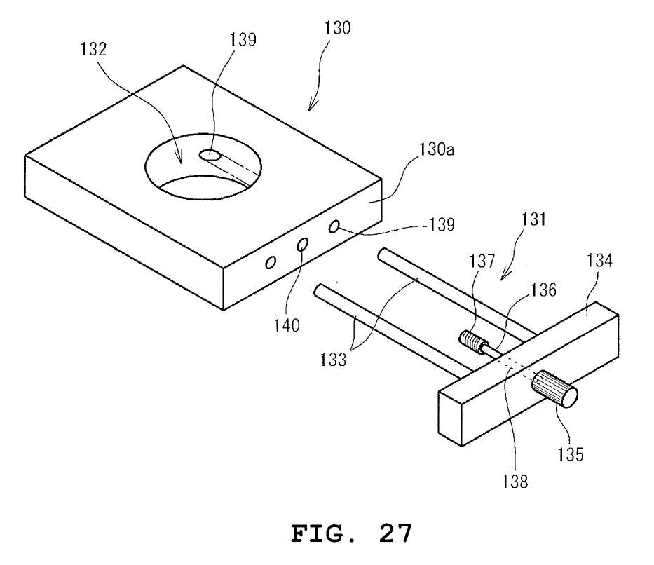

The present invention is not limited to the embodiment described above, and may be variously modified. For example, although a member provided with the lock piece and ring body is used as the lock mechanism in the embodiment described above, a parallel bar guide 130 and parallel bar unit 131 may also be used as shown in FIG. 27.

The parallel bar guide 130 is a substantially square plate with a circular opening 132 disposed in the center, and is anchored to the back surface of the base 42 so that the opening 132 is concentric to the opening 42c of the base 42.

The parallel bar unit 131 is configured by two mutually parallel bars 133, base 134 to which the parallel bars 133 are attached, and a knob 135 disposed in the center of the base 134. A shaft 136 extends from one end of the knob 135, and a male threaded part 137 is formed on the tip end of the shaft 136. The shaft 136 is inserted in a through hole 138 formed in the base 134 so as to be rotatively movable.

The parallel bar plate 130 is provided with a hole 139 into which the bar 133 can be inserted, and the front surface 130a of the parallel bar guide 130 is provided with a threaded hole 140 into which can be screwed the make threaded part 137 on the tip end of the shaft 136.

When locking the detection device, the bars 133 of the parallel bar unit 131 are inserted into the holes 139 of the parallel bar plate 130. Then, after the male threaded part 137 on the tip end of the shaft 136 contacts the threaded hole 140, the knob 135 is rotated to screw the male threaded part 137 into the threaded hole 140. The parallel bar unit 131 is thus attached to the parallel bar guide 130.

The bars 133 of the parallel bar guide 131 are set at the positions of the holes 139 so as to cross the opening 132 of the parallel bar guide 130. Part of the bars 133 that cross the opening 132 is inserted in a channel formed on the outer surface of the small diameter part of the mounting fixture disposed within the opening 132. Thus, the vertical and lateral movement of the detection device is regulated, and the detection device anchoring is complete.

When releasing the lock of the detection device, the knob 135 is rotated in the opposite direction, the male threaded part 137 is extracted from the threaded hole 140, and the parallel bar unit 131 is drawn forward to remove the bars 133 from the holes 139. The detection device is thus unlocked.

Although the present embodiment has been described by way of example in which the mounting fixture 20 and detection body 30 are separate, the present invention is not limited to this example inasmuch as the mounting fixture 20 and detection body 30 also may be integratedly formed as a single unit.

Although the present embodiment has been described by way of example in which the detection device is supported by the foam elastic body 46 of a piece formed in an annular configuration, the present invention is not limited to this example inasmuch as the foam elastic body also may be divided among a plurality of pieces so that the detection device is supported by a plurality of foam elastic bodies 46.

Although the present embodiment has been described by way of example in which the particle diameter is obtained by the controller 59 provided within the particle diameter measuring apparatus 1, the present invention is not limited to this example inasmuch as the particle diameter also may be obtained by, for example, sending the characteristic data obtained by the digital signal processor 584 to an external computer, and analyzing the characteristic data in the external computer.

Although the present invention describes a particle diameter measuring apparatus of the electrical resistance type, the present invention is not limited to this example. For example, the present invention also may be applied to a particle diameter measuring apparatus of the optical type. In this case, the configuration may provide a detection device that allows passage of particles through the interior thereof, a detection device supporting part that includes an elastic body to support the detection device through the elastic body, and a signal obtainer for obtaining signals from particles that pass through the interior of the detection device.

The present embodiment has been described by way of example that uses an elastic body configured by a foam elastic body and spring to block vibration from propagating to the detection device. However, the present invention is not limited to this example inasmuch as a gel material also may be used as the material for supporting the detection device insofar as the gel material has properties that absorb or block vibration.

Although the present embodiment describes a particle diameter measuring apparatus, the present invention is also applicable to apparatuses for measuring particles in a particle suspension liquid.

What is claimed is:

1. A particle measuring apparatus comprising:
a detection device with an aperture through which pass particles contained in a particle suspension liquid, for detecting a signal generated when a particle passes through the aperture; and
a detection device supporting part comprising an elastic body, for supporting the detection device through the elastic body.

2. The particle measuring apparatus of claim 1, wherein
the detection device is detachably supported by the detection device supporting part.

3. The particle measuring apparatus of claim 1, wherein
the detection device comprises a bottom part comprising an internal flow path connected to the aperture, and a top part comprising a protrusion; and
the detection device supporting part supports the protrusion of the detection device through the elastic body.

4. The particle measuring apparatus of claim 3, wherein
the protrusion is a flange.

5. The particle measuring apparatus of claim 1, wherein
the elastic body is a foam elastic body.

6. The particle measuring apparatus of claim 3, wherein
the detection device is supported by the detection device supporting part only through the protrusion.

7. The particle measuring apparatus of claim 3, wherein
the detection device comprises a mounting fixture, and a detection body removably mounted on the mounting fixture;
the detection body having the aperture and a first flow path;
wherein the mounting fixture comprises the protrusion disposed at the top thereof, the mounting part disposed at the bottom thereof, and a second flow path disposed therein;
and wherein the internal flow path comprises the first flow path and the second flow path.

8. The particle measuring apparatus of claim 7, wherein
the detection device supporting part comprises a buffer comprising the elastic body, a mounting surface for mounting the buffer, and a base with an opening of a size allowing passage of the mounting part of the mounting fixture;
the mounting part of the mounting fixture is configured so as to protrude from the opening of the base downwardly when the protrusion is supported on the detection device supporting part through the elastic body.

9. The particle measuring apparatus of claim 7, wherein
the buffer has a top plate disposed above the elastic body, and a bottom plate disposed below the elastic body;
the protrusion of the detection device is fixed to the top plate; and
the bottom plate is fixed to the base.

10. The particle measuring apparatus of claim 7, wherein
the detection device comprises an installation fixture for fixing the detection body to the mounting fixture;
a flange is formed at the top end of the detection body;
the mounting part of the mounting fixture has a first screw;
the installation fixture has a supporting part for supporting the flange of the detection device from below, and a second screw for engaging the first screw, wherein the detection body is fixed to the mounting fixture by the engagement of the first screw and the second screw when the flange is supported by the supporting part.

11. The particle measuring apparatus of claim 8, wherein
the detection device supporting part comprises a lock mechanism for anchoring the mounting fixture, which protrudes downward through the opening of the base, to the detection supporting part.

12. The particle measuring apparatus of claim 11, wherein
the lock mechanism comprises a pair of grips capable of gripping the mounting fixture, and an anchor fixture for anchoring both grips while both grips are gripping the mounting fixture.

13. The particle measuring apparatus of claim 1, further comprising:
an aspirator for aspirating particle suspension liquid through the flow path and aperture of the detection device; and
an analysis unit for obtaining a particle diameter based on the signal obtained when a particle of the particle suspension liquid passes through the aperture.

14. A particle measuring apparatus, comprising:
a detection device with an aperture through which passes particles contained in a particle suspension liquid;
a detection device supporting part comprising an elastic body, for supporting the detection device through the elastic body;
electrodes for applying a voltage to the particle suspension liquid; and
a signal obtainer for obtaining signals based on the change in electrical resistance when a particle contained in the particle suspension liquid passes through the aperture.

15. A particle measuring apparatus comprising:
a detection device through which particles can internally pass through;
a detection device supporting part comprising an elastic body, for supporting the detection device through the elastic body; and
a signal obtainer for obtaining signals from particles passing through the interior of the detection device.

16. A particle measuring apparatus comprising:
a detection device with an aperture through which passes particles contained in a particle suspension liquid; and
a detection device supporting part comprising a vibration absorbing member, for supporting the detection device through the vibration absorbing member.
